(19) United States
(12) Patent Application Publication
(10) Pub. No.: US 2010/0164336 A1
(43) Pub. Date: Jul. 1, 2010

(54) RECEIPT TYPE DISPLAY DEVICE

(75) Inventor: Jong Gu Lee, Seoul (KR)

Correspondence Address: HYUN JONG PARK;Park & Associates IP Law LLC, 265 Bic Drive, Suite 106, Milford, CT, 06461, US

(73) Assignee: STARPATH CO., LTD, Seoul (KR)

(21) Appl. No.: 11/721,030

(22) PCT Filed: Dec. 8, 2005
(86) PCT No.: PCT/KR2005/004194

§ 371 Date: Jun. 6, 2007

(30) Foreign Application Priority Data
Dec. 10, 2004 (KR) 10-2004-0104380

(51) Int. Cl. H05K 5/02

(52) U.S. Cl. 312/29

(57) ABSTRACT

Disclosed herein is a receptacle display device. According to this invention, a first rotary panel is mounted to a display panel support unit in such a way as to rotate about a rotating shaft, and a display panel is secured to the first rotary panel. Thus, when the first rotary panel rotates about the rotating shaft at about 90 degrees, the length of the display panel is changed to the width, and the width of the display panel is changed to the length, thus being capable of storing a large display panel, which is larger than the width of a receptacle housing, in the receptacle housing.

### TECHNICAL FIELD

The present invention relates, in general, to a retractable display device and, more particularly, to a retractable display device, which allows a larger-sized display panel to be mounted to the device within a width of a receptacle housing.

### BACKGROUND ART

As well known to those skilled in the art, a retractable display device is advantageous in that it efficiently utilizes space, and safely stores a display panel in a receptacle housing. Owing to these advantages, the retractable display device is mainly applied to car audio/video systems, navigation systems, car televisions, etc.

As shown in FIGS. 1 and 2, a conventional retractable display device which is manually driven includes a receptacle housing 100, a display panel support unit 200, and a display panel 300. The receptacle housing 100 has a receptacle space 100a therein. The display panel support unit 200 is removably inserted into the receptacle space 100a of the receptacle housing 100. The display panel 300 is mounted to the display panel support unit 200. As shown in FIGS. 1 and 2, the display panel support unit 200 includes a slide panel 210 and a support panel 220. The slide panel 210 rectilinearly reciprocates forwards and backwards in the receptacle space 100a of the receptacle housing 100. The support panel 220 is secured to an outer end of the slide panel 210 in such a way as to rotate about a rotating shaft h1. In this case, the display panel 300 is mounted to the support panel 220.

The operation of the conventional retractable display device will be described below.

In the state where the display panel 300 is inserted and received in the receptacle housing 100, as shown in FIG. 1, an end of the support panel 220 exposed to the outside of the receptacle housing 100 is pulled forwards. At this time, the receptacle housing 100 is disengaged from the display panel support unit 200, so that the slide panel 210 and the support panel 220 are pulled out. Thereafter, when the support panel 220 is lifted up, the support panel 220 rotates about the rotating shaft h1 so as to be vertically erected. The display panel 300 mounted to the support panel 220 is exposed to the front of the display device, as shown in FIG. 2.

When a user desires to store the display panel 300, exposed to the outside, in the receptacle housing 100, the display panel 300 is inserted into the receptacle space 100a of the housing 100 in the reverse procedure.

In this case, since the engagement structure of the receptacle housing 100 and the display panel support unit 200 is widely known to people, it will not be described herein.

As shown in FIGS. 3 and 4, a conventional retractable display device which is driven semi-automatically is characterized in that it is provided with a first elastic support member 10 and a second elastic support member 20. The first elastic support member 10 elastically supports the slide panel 210 in one direction. The second elastic support member 20 elastically supports the support panel 220 such that the support panel 220 rotates in one direction. Generally, the first elastic support member 10 uses a coil spring, and the second elastic support member 20 uses a torsion spring.

The operation of such a conventional retractable display device will be described below.

In the state where the display panel 300 is inserted into the receptacle housing 100, as shown in FIG. 3, the end of the support panel 220 exposed outside the receptacle housing 100 is lightly pushed backwards. At this time, the receptacle housing 100 is disengaged from the display panel support unit 200. The slide panel 210 and the support panel 220 are automatically pulled forwards by the first elastic support member 10. Thereafter, the support panel 220 rotates about the rotating shaft h1 and is lifted up by the second elastic support unit 20. Thereby, the display panel 300, mounted to the support panel 220, is exposed to the front of the display device, as shown in FIG. 4.

When a user desires to store the display panel 300, exposed to the outside, in the receptacle housing 100, the support panel 220 rotates about the rotating shaft h1 in the opposite direction, thus requiring continuous downward pressure. The slide panel 210 and the support panel 220 are pushed backwards to be inserted into the receptacle housing 100, so the display panel support unit 200 is secured to the receptacle housing 100.

In this case, since the engagement structure of the receptacle housing 100 and the display panel support unit 200 is widely known to people, it will not be described herein.

In the conventional semi-automatically driven retractable display device, as shown in FIGS. 3 and 4, the support panel 220 is elastically supported to be rotated in one direction by the second elastic support member 20. Thus, when using and storing the display panel 300, frictional interference between the receptacle housing 100 and the support panel 220 is high. Further, when the display panel 800 is pushed into the receptacle space 100a of the receptacle housing 100, the support panel 220 requires continuous downward pressure, thus causing inconvenience.

In order to solve the problems, another conventional retractable display device, which is semi-automatically driven and shown in FIGS. 5 and 6, has been proposed and used.

The display device is characterized by a third elastic support member 30. The third elastic support member 30 includes a support bar 31, a movable pin 32, and a coil spring 33. The support bar 31 is secured to the slide panel 210 in such a way that one end of the support bar 31 rotates about a rotating shaft h2. The movable pin 32 is rotatably secured to a free end of the support bar 31, and is movably inserted into a guide groove 221 of the support panel 220. The coil spring 33 is secured at opposite ends thereof to the rotating shaft h1 and the movable pin 32, thus elastically biasing the rotating shaft h1 and the movable pin 32 in both directions.

The operation of such a conventional retractable display device will be described below.

In the state where the display panel 300 is inserted into the receptacle housing 100 to be stored therein, as shown in FIG. 5, an end of the support panel 220 which is exposed to the outside of the receptacle housing 100 is lightly pushed backwards. At this time, the receptacle housing 100 is disengaged from the display panel support unit 200, so the slide panel 210 and the support panel 220 are automatically moved forwards by the first elastic support member 10. Thereafter, when the support panel 220 is lifted up, the support panel 220 rotates about the rotating shaft h1 and stably maintains an erected state due to the third elastic support member 30. Thereby, the display panel 300 mounted to the support panel 220 is exposed to the front of the display device, as shown in FIG. 6.

When a user desires to store the display panel 300, exposed to the outside, in the receptacle housing 100, the support panel 220 is rotated about the rotating shaft h1 in the opposite direction and is pressed downwards. Afterwards, the slide panel 210 and the support panel 220 are pushed backwards to be received in the receptacle housing 100. At this time, the support panel 220 is pressed downwards by the third elastic support member 30, thus maintaining an unfolded state.

As shown in FIGS. 7 and 8, a conventional automatically driven retractable display device is characterized by a slide panel drive unit 410 and a support panel rotating unit 420. The slide panel drive unit 410 rectilinearly reciprocates the slide panel 210 forwards and backwards. The support panel rotating unit 420 rotates the support panel 220 in both directions. Generally, the slide panel drive unit 410 uses a conventional motorized drive device having a drive gear 410 and a rack 412. The support panel rotating unit 420 uses a conventional motorized drive device having a drive gear 421 and a driven gear 422. Reference numerals 413 and 423 denote power transmission gears which engage with corresponding drive gears 411, 421 and corresponding driven gears 412, 422, thus transmitting power from the drive gears 411, 421 to the driven gears 412, 422.

According to the prior art, as shown in FIGS. 7 and 8, the horizontal reciprocating motion of the slide panel 210, and the folding and unfolding operation of the support panel 220 relative to the rotating shaft h1 are automatically executed by the slide panel drive unit 410 and the support panel rotating unit 420, thus considerably enhancing the convenience of use.

FIGS. 9 and 10 show another conventional retractable display device which is automatically driven. The display device is characterized in that a rack panel 230, having on a rear portion thereof an arc-shaped curved part 230a and on at least one surface thereof a guide groove 231, is applied to the display panel support unit 200, and a guide protrusion 110 fitted into the guide groove 231 of the rack panel 230 is provided in the receptacle space 100a of the receptacle housing 100, and a rack panel drive unit 430 is provided to reciprocate the rack panel 230 forwards and backwards.

The display device is advantageous in that the number of components is dramatically reduced, so that the construction is simplified and the cost of products is considerably reduced.

In addition to the above-mentioned display devices, various types of display devices have been proposed and embodied.

However, the conventional retractable display devices are problematic in that the display panel 300 is firmly secured to the display panel support unit 200, as shown in FIG. 11, so that the size of the display panel 300 is limited. It will be described below in detail.

In the case of a display panel that outputs simple data, such as numbers or questions, in the form of images, the display panel may have various widths WL and lengths LL, according to the intended purpose. However, in the case of a display panel, such as a television or a monitor, which outputs images or moving images, the ratio of width WL to length LL is internationally standardized (width WL is greater than length LL).

In the conventional retractable display devices, the display panel 300 is firmly secured to the display panel support unit 200. Thus, in order to install a larger display panel 300, the width of the receptacle housing 100 accommodating the display panel 300 must be inevitably increased in proportion to the width WL of the display panel 300.

However, if a part of a vehicle where the retractable display device is mounted is a place where it is difficult to increase the width of the receptacle housing 100, for example, an instrument panel of the vehicle, the size of the display panel 300 must be limited to correspond to the width of the receptacle housing 100.

Therefore, the conventional retractable display device is problematic in that it is impossible to satisfy a user who wants to view a larger screen.

### DISCLOSURE OF INVENTION

### Technical Problem

Accordingly, the present invention has been made keeping in mind the above problems occurring in the prior art, and an object of the present invention is to provide a retractable display device which allows a large display panel to be efficiently mounted without unreasonably increasing the width of a receptacle housing.

### Technical Solution

In order to accomplish the object, the present invention provides a retractable display device, including a receptacle housing having a receptacle space; a display panel support unit removably mounted to the receptacle space of the receptacle housing; and a display panel mounted to the display panel support unit, wherein a first rotary panel is mounted to the display panel support unit in such a way as to rotate about a rotating shaft, and the display panel is secured to the first rotary panel.

### BRIEF DESCRIPTION OF THE DRAWINGS

FIGS. 1 and 2 are left sectional views showing important parts of a conventional retractable display device which is manually driven;

FIGS. 3 and 4 are left sectional views showing important parts of a conventional retractable display device which is semi-automatically driven;

FIGS. 5 and 6 are left sectional views showing important parts of another conventional retractable display device which is semi-automatically driven;

FIGS. 7 and 8 are left sectional views showing important parts of a conventional retractable display device which is automatically driven;

FIGS. 9 and 10 are left sectional views showing important parts of another conventional retractable display device which is automatically driven;

FIG. 11 is a perspective view showing a conventional retractable display device, in which a display panel is exposed outside;

FIG. 12 is a left sectional view showing important parts of a retractable display device, according to the present invention;

FIGS. 13 and 14 are front views illustrating the operation of the retractable display device, according to the present invention, in which a display panel is exposed outside;

FIGS. 15 to 18 are left sectional views showing important parts of a retractable display device, according to the first embodiment of the present invention;

FIG. 19 is a view corresponding to FIG. 18, but showing a retractable display device, according to the second embodiment of the present invention;

FIG. 20 is an enlarged sectional view showing important parts of the retractable display device of FIGS. 19; and

FIG. 21 is a plan view illustrating the operation of the retractable display device of FIG. 19, in which a display panel is exposed outside.

### MODE FOR THE INVENTION

Hereinafter, the present invention will be described in detail with reference to the accompanying drawings.

A retractable display device according to the present invention includes a receptacle housing 100, a display panel support unit 200, and a display panel 300. The receptacle housing 100 has a receptacle space 100a therein. The display panel support unit 200 is removably inserted into the receptacle space 100a of the receptacle housing 100. Since the components of this invention are identical with the components of the conventional retractable display device, they will not be described in detail below.

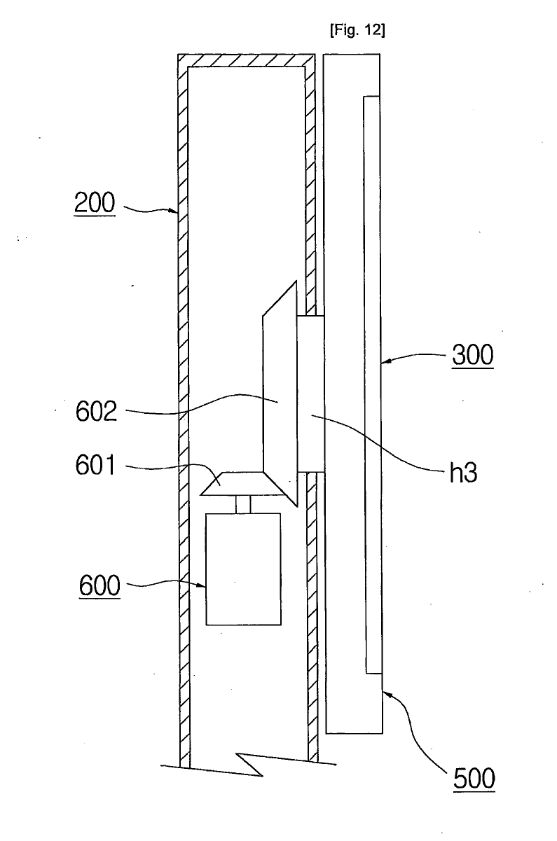

As shown in FIG. 12, the present invention is characterized in that a first rotary panel 500 is additionally mounted to the display panel support unit 200 in such a way as to rotate about a rotating shaft h3, and the display panel 300 is secured to the first rotary panel 500.

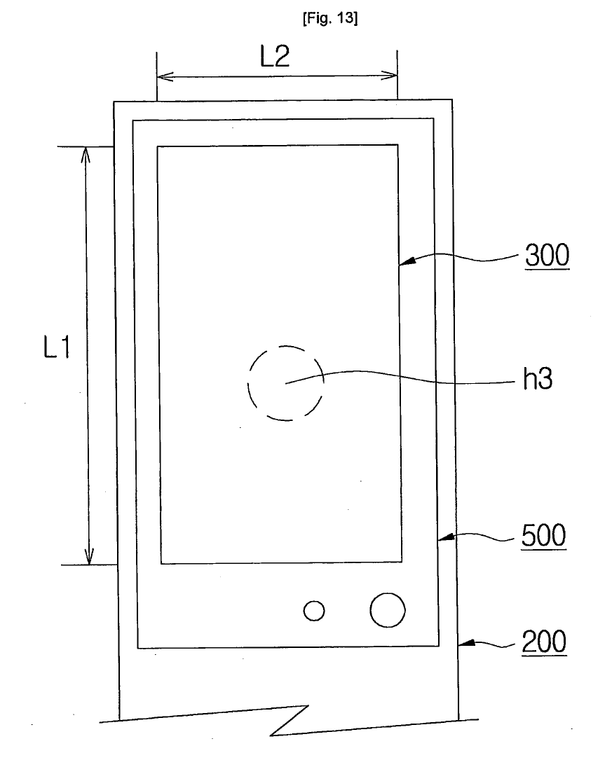

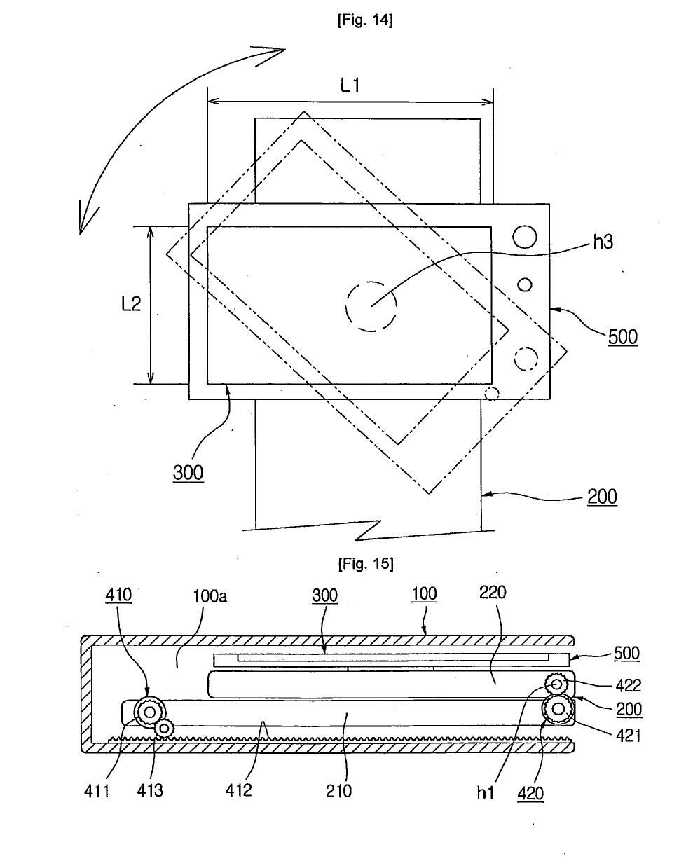

According to this invention, the display panel 300 is secured to the first rotary panel 500, and rotates about the rotating shaft h3 in both directions (clockwise and counterclockwise). Thus, after the display panel 300 is exposed to the front of the receptacle space 100a of the receptacle housing 100, as shown in FIG. 13, the first rotary panel 500 rotates about the rotating shaft h3 at about 90 degrees, as shown in FIG. 14. In this case, the length L1 of the display panel 300 is changed to the width, and the width L2 of the display panel 300 is changed to the length.

Thus, it is possible to store a large display panel 300, which is larger than the width of the receptacle housing 100, in the receptacle housing 100.

The maximum rotation angle of the first rotary panel 500 may be limited as desired. Preferably, in the state where the display panel 300 has rotated at 90 degrees, a viewer who is at a specific position may freely adjust the rotation angle of the display panel 300 within a predetermined range so that it is suitable for watching TV, by rotating the display panel 300 clockwise or counterclockwise.

The first rotary panel 500, rotatably mounted to the display panel support unit 200, must be secured to a predetermined position, in the state where the first rotary panel is not rotated or is rotated at a specific angle. Since the coupling structure of the display panel support unit 200 with the first rotary panel 500 is known to those skilled in the art and has been widely used, it will not be described herein.

The first rotary panel 500 may be manually rotated by a user's external force. However, as shown in FIG. 12, a first rotary panel drive unit 600 is mounted to rotate the first rotary panel 500 about the rotating shaft h3 in both directions (clockwise and counterclockwise), so that the first rotary panel 500 may be automatically rotated in both directions by the first rotary panel drive unit 600.

According to this embodiment, the first rotary panel drive unit 600 comprises a conventional motorized drive unit having a drive gear 601 and a driven gear 602, which are bevel gears.

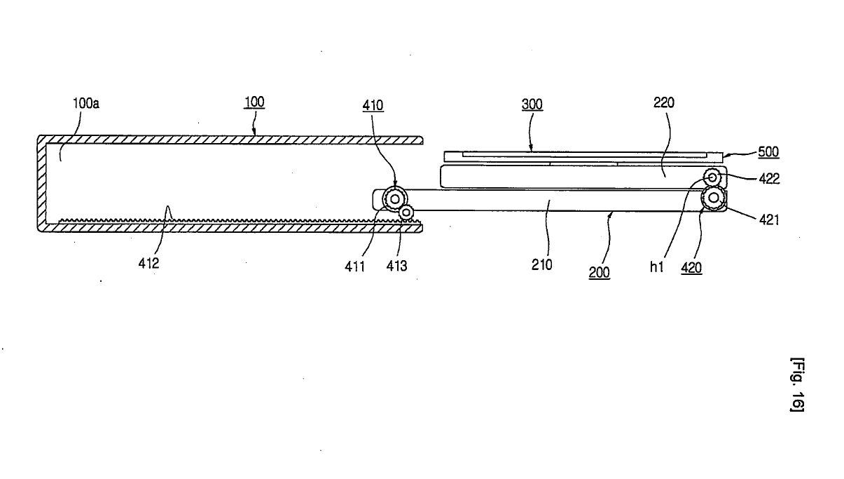

FIGS. 15 to 18 show a retractable display device, according to the first embodiment of the present invention.

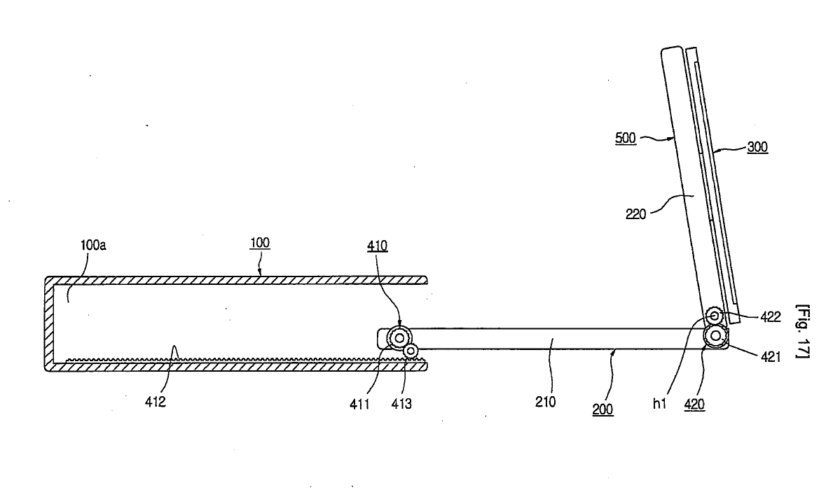

In this case, the display panel support unit 200 includes a slide panel 210 and a support panel 220. The slide panel 210 reciprocates forwards and backwards along the receptacle space 100a of the receptacle housing 100. The support panel 220 is secured to an outer end of the slide panel 210 in such a way as to rotate about a rotating shaft h1. The forward and backward motion of the slide panel 210 and the rotation of the support panel 220 about the rotating shaft h1 may be manually controlled by a user. However, according to this embodiment, as shown in FIGS. 15 and 16, the slide panel 210 is automatically driven by a slide panel drive unit 410, and the support panel 220 is rotated about the rotating shaft hl by a support panel rotating unit 420. According to the present invention, in the state where the support panel 220 is folded to overlap with the slide panel 210, it is inserted into the receptacle space 100a of the receptacle housing 100. Further, the support panel 220 is pulled forwards from the receptacle space 100a of the receptacle housing 100 while the support panel 220 is folded, and thereafter, the support panel 220 is unfolded to be vertically erected.

The operation of the retractable display device according to this embodiment will be described below.

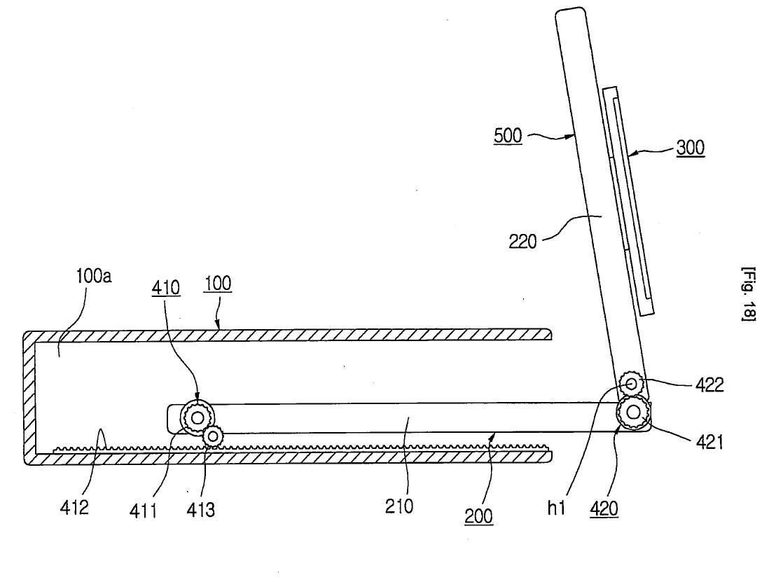

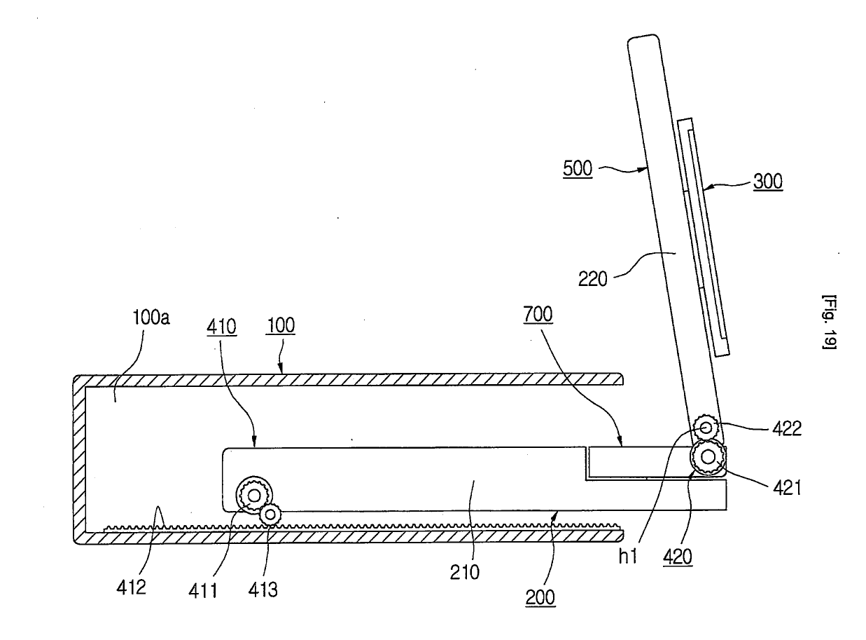

In the state shown in FIG. 15, the slide panel 210 is moved forwards by the slide panel drive unit 410, as shown in FIG. 16. Thereafter, as shown in FIG. 17, the support panel 220 is rotated about the rotating shaft hl by the support panel rotating unit 420 to be erected at a predetermined angle. Afterwards, the slide panel 210 is moved backwards by the slide panel drive unit 410 so that the support panel 220 is spaced apart from the receptacle housing 100 by a predetermined interval, as shown in FIG. 18.

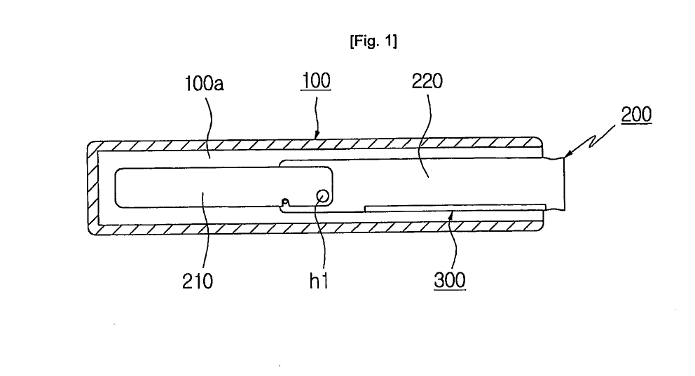

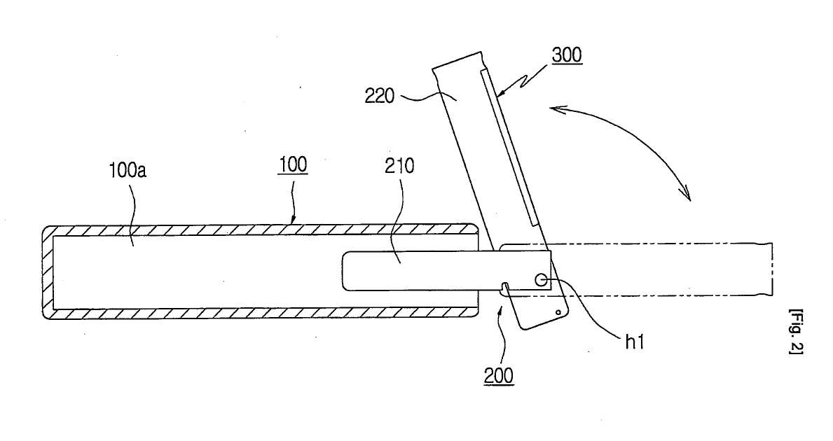

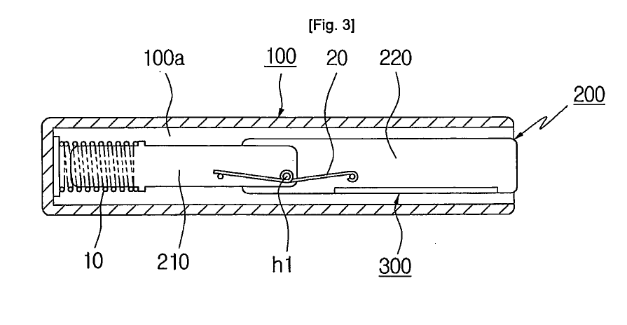

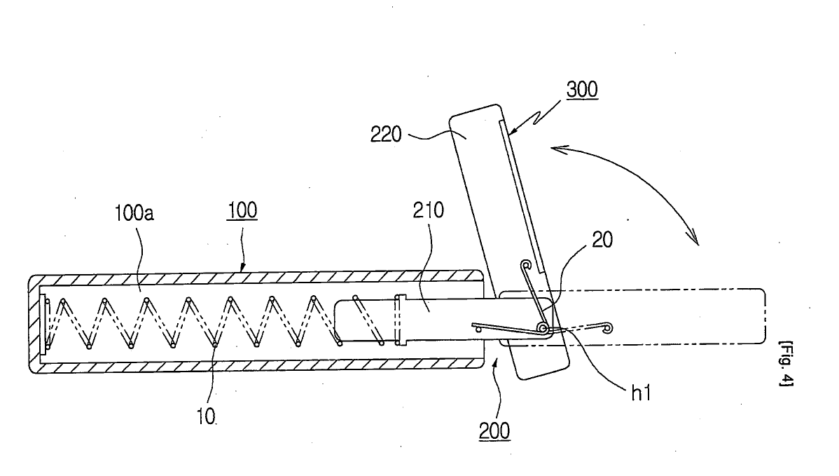

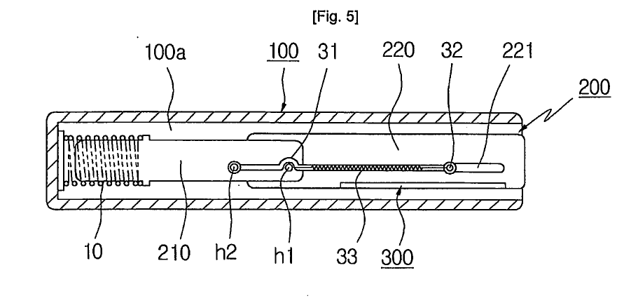

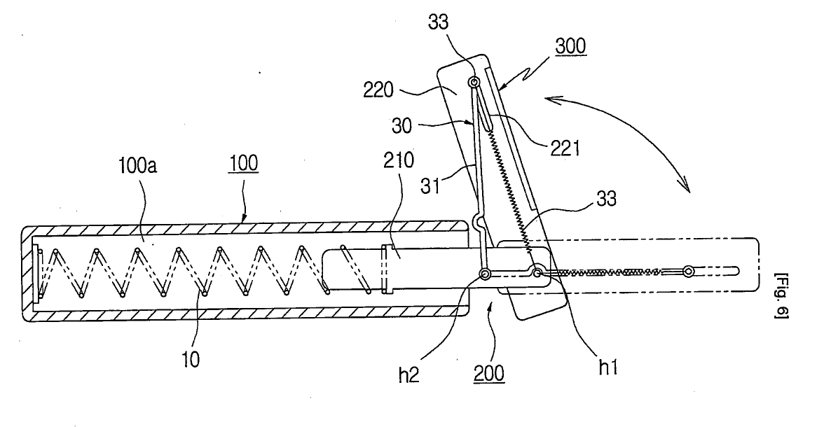

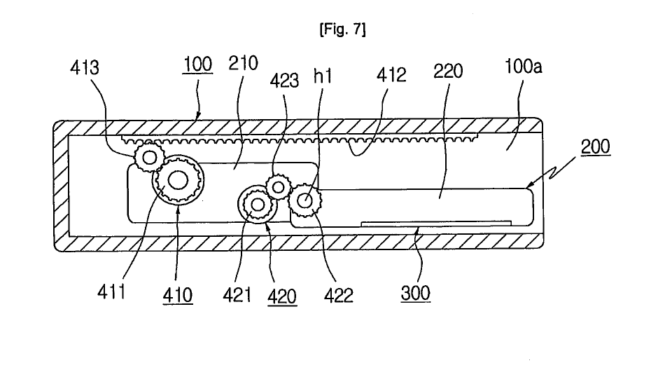

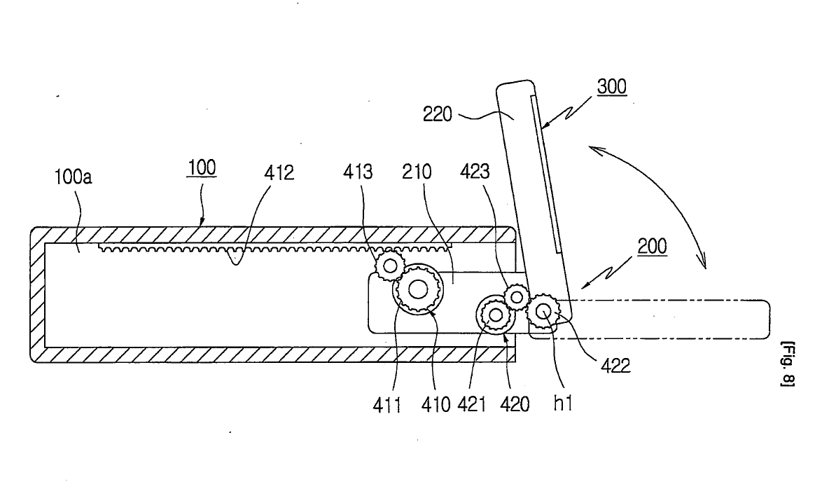

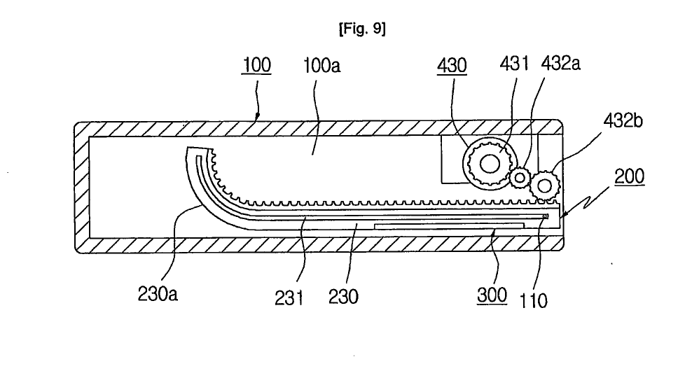

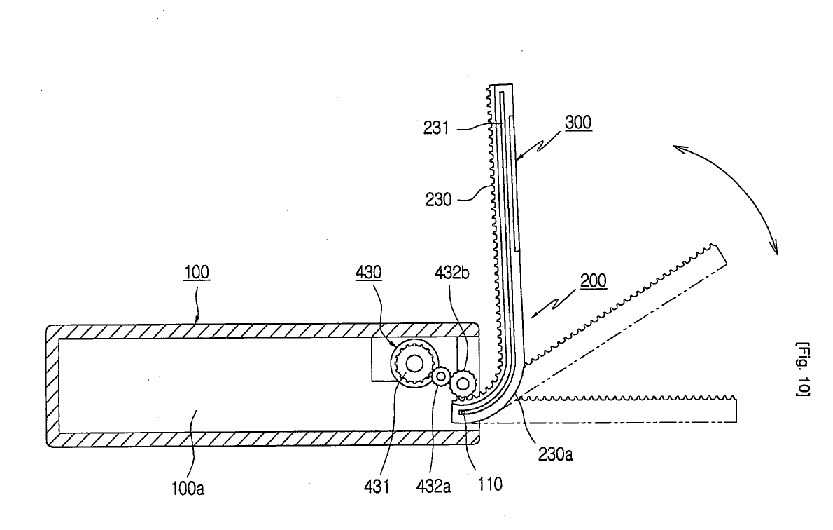

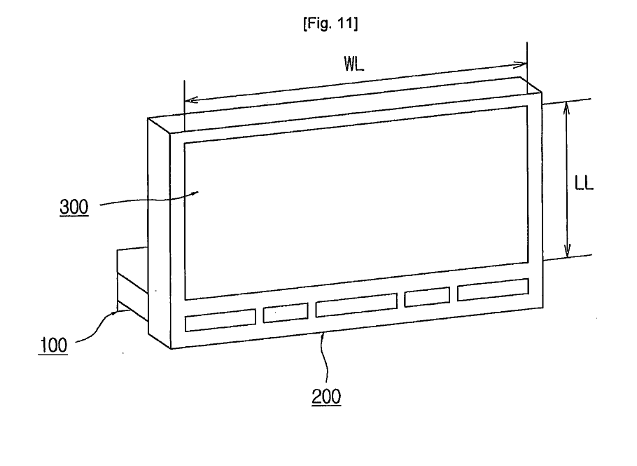

This embodiment is advantageous for efficiently increasing the vertical length L1 of the display panel 300, in comparison with the prior art, wherein the support panel and the slide panel are inserted into the receptacle space 100a of the receptacle housing 100 with the support panel 220 being unfolded along the same line as the slide panel 210, and the support panel 220 is pulled to the front of the receptacle space 100a of the receptacle housing 100 with the support panel being unfolded, and then is folded to be erected, as shown in FIGS. 1 to 8.

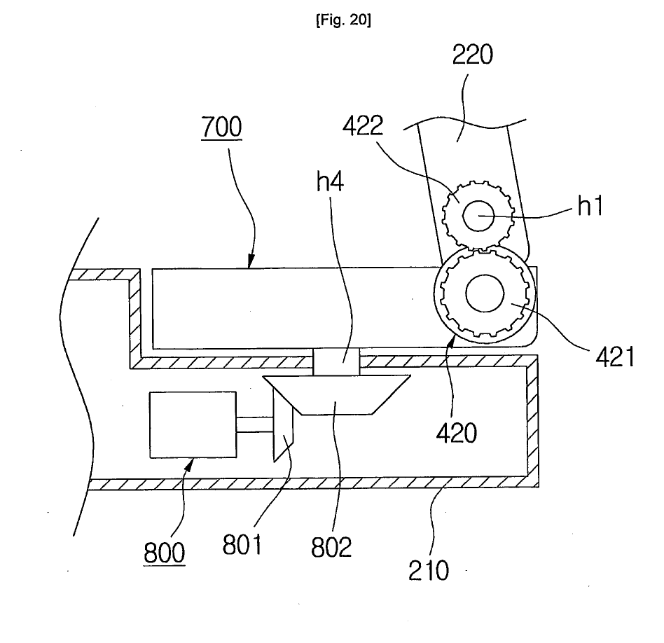

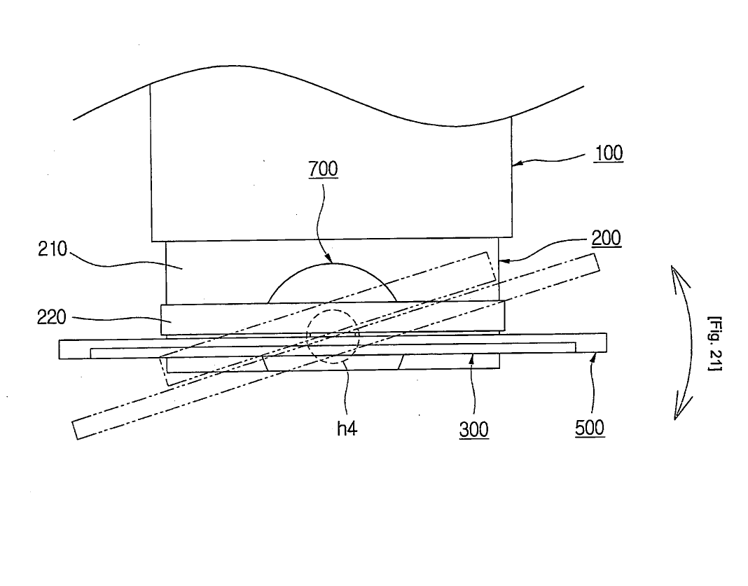

FIG. 19 shows a retractable display device, according to the second embodiment of the present invention. According to this embodiment, a second rotary panel 700 is mounted to the front surface of the slide panel 210 in such a way as to rotate about a rotating shaft h4 in both directions, and the support panel 220 is secured to the second rotary panel 700 in such a way as to rotate about the rotating shaft h1. The second rotary panel 700 may be manually rotated by a user's external force. However, according to this embodiment, as shown in FIG. 20, a second rotary panel drive unit 800 is mounted to rotate the second rotary panel 700 about the rotating shaft h4 in both directions (leftwards and rightwards), so that the second rotary panel 700 is automatically rotated in both directions by the second rotary panel drive unit 800. The second rotary panel drive unit 800 uses a conventional motorized drive unit having a drive gear 801 and a driven gear 802, which are bevel gears.

According to this embodiment, a viewer who is at a specific position may rotate the display panel 300 leftwards or rightwards to be suitable for watching the display panel, as shown in FIG. 21, thus satisfactorily enabling watching of the display panel 300 without limiting a viewer's position.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

### INDUSTRIAL APPLICABILITY

As described above, according to the present invention, a first rotary panel 500 is Mounted to a display panel support unit 200 in such a way as to rotate about a rotating shaft h3, and a display panel 300 is secured to the first rotary panel 500. Thus, when the first rotary panel 500 rotates about the rotating shaft h3 at about 90 degrees, the length L1 of the display panel 300 is changed to the width, and the width L2 of the display panel 300 is changed to the length, thus being capable of storing a large display panel 300, which is larger than the width of a receptacle housing 100, in the receptacle housing 100.

Therefore, the present invention allows a large display panel to be efficiently mounted without unreasonably increasing the width of the receptacle housing, thus remarkably enhancing marketability.

1. A retractable display device, comprising a receptacle housing having a receptacle space; a display panel support unit removably mounted to the receptacle space of the receptacle housing; and a display panel mounted to the display panel support unit, wherein a first rotary panel is mounted to the display panel support unit in such a way as to rotate about a rotating shaft, and the display panel is secured to the first rotary panel.

2. The retractable display device according to claim 1, wherein the display panel support unit comprises: a slide panel reciprocating forwards and backwards along the receptacle space of the receptacle housing; and a support panel secured to an outer end of the slide panel in such a way as to rotate about a rotating shaft, wherein the support panel is stored in the receptacle space of the receptacle housing while being folded to overlap with the slide panel, and the support panel is pulled forwards from the receptacle space of the receptacle housing while being folded, and is then unfolded and erected.

3. The retractable display device according to claim 2, further comprising: a slide panel drive unit to reciprocate the slide panel forwards and backwards; and a support panel rotating unit to rotate the slide panel in both directions.

4. The retractable display device according to claim 2, further comprising: a second rotary panel mounted to a front surface of the slide panel in such a way as to rotate about a rotating shaft in both directions, the support panel being secured to the second rotary panel in such a way as to rotate about a rotating shaft.

5. The retractable display device according to claim 4, further comprising: a second rotary panel drive unit to rotate the second rotary panel about the rotating shaft in both directions.

6. The retractable display device according to claim 1, further comprising: a first rotary panel drive unit to rotate the first rotary panel about the rotating shaft in both directions.

7. The retractable display device according to claim 2, further comprising: a first rotary panel drive unit to rotate the first rotary panel about the rotating shaft in both directions.
